(19) United States
(12) Patent Application Publication
(10) Pub. No.: US 2015/0099069 A1
(43) Pub. Date: Apr. 9, 2015

(54) LOW-COST PLASMA REACTOR

(71) Applicant: AeonClad Coatings, LLC Technologies, Inc., Austin, TX (US)

(72) Inventors: Rupert Anthony Taylor, Austin, TX (US); Daniel John Verdell Pulsipher, Austin, TX (US)

(21) Appl. No.: 14/508,222

(22) Filed: Oct. 7, 2014

Related U.S. Application Data
(60) Provisional application No. 61/887,956, filed on Oct. 7, 2013.

(51) Int. Cl. H01J 37/32; C23C 16/455; C23C 16/50

(52) U.S. Cl. CPC H01J 37/32467; C23C 16/50; C23C 16/455; H01J 37/32055; H01J 37/3211; H01J 2237/3321
USPC 427/488; 427/569; 313/231.41; 313/231.31; 137/561 R

(57) ABSTRACT

An apparatus for vacuum plasma processing materials in a vacuum chamber composed primarily of carbonaceous polymer. The various components of the vacuum chamber can be formed by traditional polymer assembly techniques. The polymers may be electrically non-conductive to allow external placement of electrodes for either capacitive coupling, inductive coupling, or both.

### PRIORITY CLAIM

This application claims priority to U.S. Provisional Application Ser. No. 61/887,956 entitled “LOW-COST PLASMA REACTOR” filed Oct. 7, 2013, which is incorporated herein by reference in its entirety.

### BACKGROUND OF THE INVENTION

1. Field of the Invention

The invention generally relates to plasma processing reactors. More particularly, the invention relates to the use of polymeric components in a plasma processing apparatus.

2. Description of the Relevant Art

The applications of non-equilibrium plasma processes include etching, surface modification and film deposition. These three plasma processes exist along a continuum of: removing molecules from a surface (etching); rearranging molecules or implanting functional groups on a surface (surface modification); and adding molecules to or coating a surface (deposition). Historically, there have been only minor variations in chamber construction materials designed for each of these three processes. Chambers designed for etching or subtractive processes are typically constructed of materials which are minimally affected by the plasmas contained within. This constraint generally mandates either metallic, ceramic, or inorganic compositions for materials of construction due to the ability of these substances to withstand repeated cycles of aggressive plasma processing. Likewise chambers used in surface modification must withstand an environment designed to break covalent bonds on the work piece. High energy particles, electrons, and short wavelength photons are generated in this process and the chamber materials need to resist these insults through multiple iterations over the life of a plasma chamber.

Deposition process conditions range widely depending on the work piece and the material being deposited. Inorganic depositions, such as those used in semiconductor fabrication, generally use elevated temperatures and high power densities; in contrast, organic depositions can occur at room temperature with very low power densities. Deposition chambers must be periodically cleaned to avoid a thick film buildup on the inner walls where the work piece is processed. A standard practice for cleaning a deposition chamber is to adjust the power, gases, and temperatures to etch away deposited films. These cleaning routines mandate a chamber design that can withstand harsh conditions which typically means metal, ceramic, or other inorganic materials are also the preferred materials for deposition chamber construction.

Typically metals have been the primary class of materials used in the construction of plasma chambers. Various grades of stainless steel and aluminum are the most commonly encountered alloys in plasma chambers with carbon steel being acceptable for some applications. Metals offer a number of favorable characteristics needed for most plasma chamber applications including strength, toughness, structural integrity at high temperatures, low outgassing, and electrical conductivity. The low rates of outgassing means that metals can be used in all vacuum regimes from low vacuum (760-25 Torr) to ultrahigh vacuum (10⁻⁹-10⁻¹² Torr) applications. There are also many well-known design and fabrication techniques for manipulating many different types of metals to provide metallic plasma chambers having the desired physical properties. These beneficial properties are offset by the need for more specialized tools if any modifications or repairs are needed. Thus, metal chambers can be difficult to upgrade or repair in the field. Because metals are opaque, viewing ports must be installed if visual observation of the plasma is desired. Metals, being electrically conductive, restrict electrode placement in a plasma chamber as external electrodes will not penetrate the chamber and internal electrodes have to be designed with coupling to the chamber in mind. These disadvantages limit the flexibility of plasma reactor designs that use metal plasma chambers.

Another class of materials commonly found in plasma chambers is ceramics, which are normally used for subassemblies within a plasma chamber. Ceramic materials are compatible with plasma environments because they are strong, can withstand high temperatures, are electrically insulating, and have minimal outgassing. Ceramics can be used at any vacuum level. Offsetting these positive attributes is that ceramic materials are expensive, brittle, and not repairable.

Glass and glass like materials, such as quartz, are capable of high temperature operation, are translucent, are strong, have minimal outgassing, and are electrically insulating. Glass materials can be used at any vacuum level, but are brittle and cannot be repaired in the field.

Plastics and polymeric materials in general are not recommended for use in vacuum systems, but there are some polymeric materials that can be used sparingly in medium (25-10⁻³ Torr) to high (10⁻³-10⁻⁹ Torr) vacuum systems namely PEEK, fluorinated polymers such as PTFE and polyimide polymers such as Vespel, Duration, and Torlon. The list of these low outgassing polymers is small and they are relatively expensive and more difficult to work with and bond together than cheaper polymeric materials such as polyvinyl chloride (PVC). Polymeric materials are not recommended for making vacuum chambers; they are not even considered for making entire plasma reactors.

Outgassing data of many polymeric materials is available in tables collected by NASA and ESA agencies. The current standard holds the material at 125° C. for 24 hours at 10⁻⁵ Torr and determines the total weight lost (TWL) of the polymeric material, the amount of volatile condensed materials (VCM) that were released from the material, and the amount of water vapor regained (WVR) by the material after it is put in a humidity at atmospheric pressure. TWL, VCM and WVR data are used to determine the efficacy of a material in space applications. This test data is useful, however, by itself, it does not determine materials that would be suitable to use in containing low pressure plasmas used in PECVD processes.

For PECVD processes, it is desirable to have a material with low to no wall permeability of unwanted atomic and molecular species at operating pressures; this could include materials with high TWL and VCM values that have been previously outgassed. Even low levels of continuous outgassing or low gas permeation through the chamber walls (attributing to typically <<5% of the total partial pressure) might be acceptable depending on the plasma processing conditions, substrate material, and final product specifications. A qualifying polymeric plasma chamber material would also resist molecular adsorption and absorption of unwanted species during processing and venting cycles as well as withstand multiple exposures to thermal, electron, and UV light radiation.

### SUMMARY OF THE INVENTION

In one embodiment, a vacuum chamber of a plasma reactor includes a body, wherein the body is composed of a polymer material. One or more ports to allow the entry of gases and monomers, one or more conduits coupled to the body, and one or more vacuum conduits are coupled to the vacuum chamber. In some embodiments, one, some, or all of the ports and conduits coupled to the vacuum chamber may be made of a polymer material. In some embodiments, a coating is formed on the interior walls of the vacuum chamber, wherein the coating layer inhibits molecular adsorption and absorption of unwanted species by the interior walls of the vacuum chamber.

In some embodiments, a plasma reactor includes a vacuum chamber as described above. The plasma reactor may also include two or more electrodes positioned outside of the polymer vacuum chamber, wherein a capacitive discharge between the electrodes creates a plasma within the polymer vacuum chamber. The plasma reactor may alternately include an electrically conductive coil surrounding the vacuum chamber, wherein passage of a current through the electrically conductive coil inductively produces a plasma within the polymer vacuum chamber.

In an embodiment, a method of making a coated substrate includes: placing the substrate to be coated in a plasma reactor as described above; introducing a monomer or reactive gas, and creating a plasma within the polymer vacuum chamber containing monomer or reactive gas.

### BRIEF DESCRIPTION OF THE DRAWINGS

Advantages of the present invention will become apparent to those skilled in the art with the benefit of the following detailed description of embodiments and upon reference to the accompanying drawings in which:

FIG. 1 depicts a schematic diagram of a plasma deposition reactor having a polymeric vacuum chamber;

FIG. 2 depicts a side view of a plasma deposition reactor having a polymeric vacuum chamber;

FIG. 3 depicts the work piece load end of a vacuum chamber;

FIG. 4 depicts a vacuum port of a vacuum chamber;

FIG. 5 depicts a monomer/gas inlet port of a vacuum chamber;

FIG. 6 depicts an assembled vacuum chamber;

FIG. 7 depicts a vacuum chamber having an acrylic end plate;

FIG. 8 depicts a plasma maintained in a fiberglass vacuum chamber;

FIG. 9 depicts an apparatus for testing a polymeric vacuum chamber materials; and

FIG. 10 is a logarithmic plot of LBR as a function of time for some materials.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

It is to be understood that the present invention is not limited to particular devices or methods, which may, of course, vary. It is also to be understood that the terminology used herein is for the purpose of describing particular embodiments only, and is not intended to be limiting. As used in this specification and the appended claims, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

A plasma is any gas in which a significant percentage of the atoms or molecules are ionized. Fractional ionization in plasmas used for deposition and related materials processing varies from about 10⁻⁴ in typical capacitive discharges to as high as 5-10% in high density inductive plasmas. Processing plasmas are typically operated in the medium vacuum regime (25-10 Torr), although arc discharges and inductive plasmas can be ignited at atmospheric pressure. Plasmas with low fractional ionization are of great interest for materials processing because electrons are so light, compared to atoms and molecules, that electrons can be maintained at very high temperatures—tens of thousands of kelvins, equivalent to several electronvolts average energy—while the neutral atoms remain at ambient temperature. This allows treatment of and film deposition on a wide variety of substrates including plastics and polymeric materials that would not be allowed in other vapor deposition processes. By adding the ability to pulse the plasma in a plasma enhanced chemical vapor deposition (PECVD) process (by using PPECVD), a greater amount of control is obtained over materials that can withstand a plasma process. Electrons are more mobile than ions and as a consequence, all surfaces in contact with the plasma acquire a negative charge and a sheath forms. Ions are accelerated across this sheath and energetically bombard, and as a consequence heat, all charged surfaces. This ion bombardment only happens during the plasma on-time and yet deposition and treatment can happen even during the plasma off-time. Thus by pulsing plasmas, heat and damage can be reduced to all contacting surfaces.

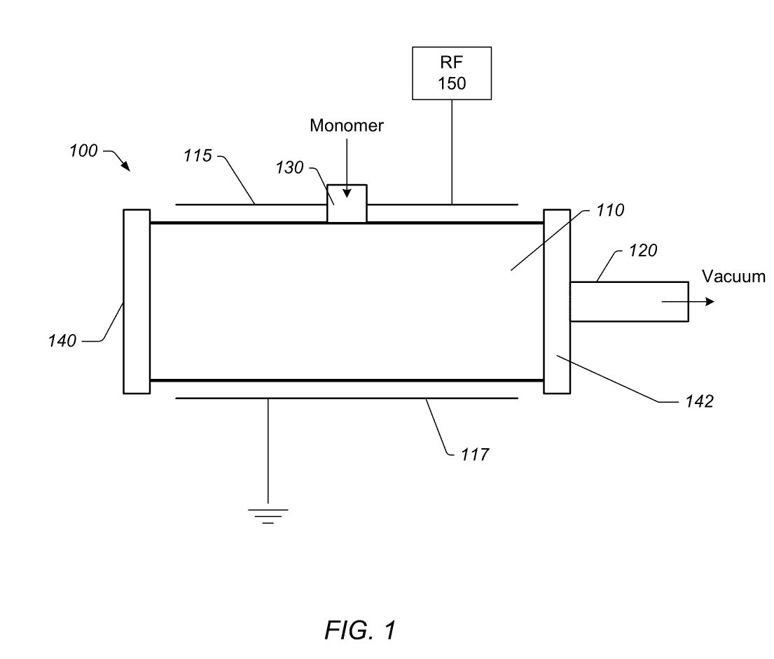

FIG. 1 depicts a schematic diagram of a typical plasma deposition reactor 100. Plasma deposition reactor includes a vacuum chamber 110, which includes vacuum outlet 120, a monomer/reactive gas inlet 130, and a sample inlet 140. Exterior to the vacuum chamber 110, two electrodes 115, 117 are placed at an appropriate spacing from each other to allow the capacitive generation of a plasma between the electrodes. An RF generator 150 is coupled to one of the electrodes (e.g., 115), and the other electrode is grounded. In another embodiment, multiple alternating RF connected and grounded ring electrodes are placed around the tube to allow more control over the spacing between electrodes. In alternate embodiments, electrodes 115 and 117 may be positioned within the vacuum chamber. In another embodiment, end caps 140 and 142 may be formed from a metal and act as electrodes. In this embodiment, one of the metal end caps (e.g., 140) may be coupled to an RF generator, while the other metal end cap (e.g., 142) is grounded. This configuration creates an electrical discharge along the length of the vacuum chamber to generate a plasma within the vacuum chamber.

During use a sample may be placed into vacuum chamber 110 through sample inlet 140. Sample inlet 140 may be a removable cover that is coupled to vacuum chamber 110 that is removed to allow introduction of the sample. After the sample is positioned in vacuum chamber 110, a vacuum is generated in the vacuum chamber. A monomer/reactive gas is introduced into the vacuum chamber through reactive gas inlet 130 and plasma is generated, either using pulsed or continuous-wave (CW) plasma.

The selection criteria for materials in the design of a plasma chamber include electrical conductivity, dielectric constant, strength, toughness, machinability, temperature range, commercial availability, outgassing, gas permeability, and resistance to attachment by plasma. These criteria must be evaluated to provide optimal performance, cost, durability and maintainability with the process conditions experienced inside the chambers. As most plasma chambers will, at some point, be operated in an etching or subtractive mode, the materials of construction must be chosen to withstand these aggressive conditions, hence the traditional choice of metals, ceramics and/or glass.

Conventional knowledge in vacuum plasma processing is that polymers (e.g., polyvinyl chloride (PVC)) are not suitable for plasma chamber construction because the PVC will continually outgas volatile gases from within the polymer or be permeable to outside gases penetrating through the polymer wall. This is evidenced by references from multiple manufacturers of PVC vacuum fittings and writers of industrial best practices who recommend polymeric fittings for rough vacuum service only. Manufactures of polymeric fittings do not recommend using such fittings for the lower vacuums used in plasma chambers.

In one embodiment, a plasma reactor may be composed, primarily, of polymeric components. It was surprising that polymeric vessels could not only be used to maintain the vacuum levels necessary for plasma processing but also that polymeric vessels could withstand the conditions present in a plasma deposition chamber over an extended series of runs. The low levels of outgassing, especially with solvent welded polymeric tubing, was unexpected based on a survey of the literature, but an even more unexpected benefit of polymeric plasma chambers was the tight sealing capacity of these chambers. This is due, in part, to the ability to fuse polymers into a single continuous part when solvent welded and the small degree of flexibility inherent in polymer structural members. By applying relatively small amounts of stress to the polymer parts, the parts can conform to any opposing surface and thereby provide a gap free sealing surface.

Advantages of polymer plasma chambers include extremely low cost of material acquisition and ease of fabrication. Commonly available, off-the-shelf materials are sufficient for construction of chambers for plasma deposition with diameters ranging from 0.5 inch to 48 inches and lengths of over 40 feet. Fittings to adapt to other parts of the reactor are also readily available in threaded, slip-joint, or gasketed configurations.

Modification and repair of the chamber can be easily accomplished in a field production environment. As an example, common hand tools are sufficient to drill or plug access ports to the chamber without removing the chamber from the reactor system and additions to the plasma chamber can be added or removed with a simple hand saw and readily available solvent welding solutions. This ease of modification allows a rapid series of iterations of not only chamber configurations but also electrode placement strategies. External capacitive or inductive coupling can easily be accommodated and, surprisingly, power transfer through the walls of the polymer chamber was efficient enough to not heat the chamber walls above softening temperatures.

The durability of the polymer plasma chambers was also surprising with over 3000 plasma cycles being recorded with no degradation of vacuum integrity. This integrity included multiple access ports, interfaces with metal components for the vacuum pump and vacuum gauges, and monomer/reactive gas addition ports. Reactors subjected to vibration have withstood service with 1600 lbs of force being applied at 9000 vibrations per minute while maintaining vacuum integrity and successfully depositing thin films on mechanically fluidized particles. This remarkable durability can be attributed to the light weight and impact resistance of polymer chambers in contrast to metal, ceramic, or glass chambers.

Safety of operators and maintenance personnel is also improved by the utilization of polymer chambers. The toughness of the chambers reduces the risk of high speed projectiles in case of a chamber implosion. The most common failure mode of a polymer chamber is the result of a temperature excursion; however, the plastic deformation of a polymer chamber ensures a slow collapse versus a rapid acceleration of glass or ceramic shards. Since polymers do not have the same projectile danger as quartz chambers, the surrounding shielding does not need to be designed to contain these projectiles thereby allowing more flexibility in shielding construction. The light weight of most polymer chamber components reduces the chance of personnel injury from crushing or lifting strains. The durability of polymer chambers means fewer replacement operations and concurrent opportunity for injury. From an eye safety perspective, most polymers, and especially the polymers described herein, are excellent shielding materials for ultraviolet light. Finally, since the polymer chamber is nonconductive, there is reduced opportunity for inadvertent electrical shocks from stray electrical currents riding on the walls of the chamber.

Polymer chambers constructed from drawn polymer pipe are also very smooth on the interior surfaces. With careful technique, these pipes can readily be assembled into chambers with no crevices to retain particulate matter. This can be important when the work piece is sensitive to dust contamination or when processing powdered material to ensure a uniform residence time in the plasma zone.

The lightweight, low cost, and ease of modification of polymer chambers means that a reactor system can be readily constructed with multiple interchangeable chambers. This allows rapid switching between different chemistries without the need to first clean the plasma chambers. In a production setting, this flexibility greatly increases productivity and reduces processing costs. A summary of some of the properties of different chamber materials to support the discussed advantages is given in Table 1.

TABLE 1

| Vessel Propertires | PVC | Fiberglass | Stainless Steel (316) | Glass | Ceramic (Alumina) |
|---|---|---|---|---|---|
| Obtained Pressure (Torr) | 8 × 10⁻⁴ | 1 × 10⁻³ | 1 × 10⁻¹² | 1 × 10⁻¹² | 1 × 10⁻⁹ |
| Cost ($/cm³) | 0.03 | 0.03 | 0.23 | 0.10 | 1.10 |
| Density (g/cm³) | 0.549-1.85 | 2.58 | 7.85 | 2.4 | 3.42 |
| Dielectric Strength (kV/cm) | 180-400 | 200 | Null | 100-400 | 80-150 |
| External Electrode Compliant | Yes | Yes | No | Yes | Yes |
| Ultimate Tensile Strength (MPa) | 3.74-55 | 55 | 538 | 282 | 115-160 |
| Stress Intensity Factor (MPa * m^{0.5}) | 2.0-4.7 | 0.79 | 28-36 | 0.26-0.29 | 3.0-4.0 |
| Crack Resitant/Not Brittle | Yes | Moderate | Yes | No | Moderate |
| Thermal Conductivity (W/m/K) | 0.14-0.19 | 0.04 | 13-17 | 1.2 | 13.0-17.0 |
| Max Operating Temperature (° C.) | 52 | 121 | 815 | 260 | 3000 |
| Ease of Construction | Easy - Pieces | Easy - Pieces | Difficult - Requires | Difficult - | Difficult - Requires |
| | are solvent | are connected | welding and machine | Requires high | furnace and other |
| | welded and can | with epoxy and | tools. | temperature | specialty equipment |
| | be formed with | formed with | | glass working | to produce. |
| | common hand | common hand | | equipment. | |
| | tools. | tools. | | | |

In some embodiments, one or more components of a plasma reactor may be formed from a clear polymer material. Clear chamber walls, afforded by constructing with a clear polymer, allows easy inspection of the plasma distribution and intensity along long distances. For example, a 20 foot long by 1 foot diameter clear polymer tube was used to evaluate gas feed positions and flow rates by monitoring the intensity of the plasma glow discharge. To achieve similar granularity with a metal tube would require visualization ports continuously down the length of the chamber. Quartz would be an acceptable alternative for monitoring plasma intensity but a single chamber of that dimension would require an extensive annealing process. These restrictions effectively eliminate the possibility of performing fine scale optimization experiments from the realm of economic feasibility.

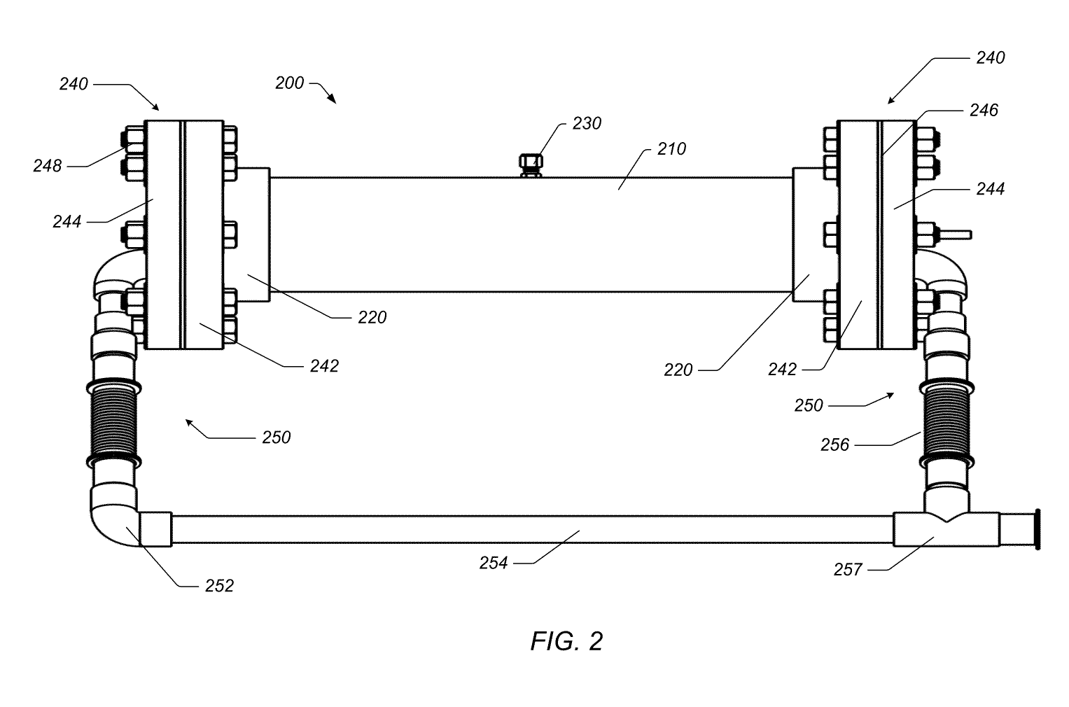

An embodiment of a polymer plasma reactor 200 is depicted in FIG. 2. A plasma reactor includes a vacuum chamber 210, vacuum outlets 220, and one or more monomer/reactive gas inlets 230. Vacuum outlets 220 are coupled to one or more fittings 240 and conduits 250, which allow the vacuum outlets to be coupled to a vacuum source (e.g., a vacuum pump). Vacuum chamber 210, vacuum outlets 200 and most, if not all, of the fittings 240 and conduits 250 may be formed from a polymer material.

In an embodiment, vacuum chamber 210 is formed from a polymer. Vacuum chamber may, in some embodiments, be formed from a clear (transparent or translucent) polymer. A variety of polymers may be used for forming a vacuum chamber of a plasma reactor. For example, vacuum chamber may be formed from an acrylic polymer or clear polyvinyl chloride (PVC). Vacuum chamber 210 may be formed from commercially available piping, typically used or water, gas, and other plumbing applications. For applications that require the use of a high temperature plasma, polymers rated for high temperature applications may be used. For example, fiber reinforced polymer (FRP) may be used for high temperature applications. Fibers used in fiber reinforced polymers include, but are not limited to, glass, carbon, basalt, aramid, paper, wood, and asbestos. Polymers include, but are not limited to, epoxies, vinylesters, polyesters, and phenol formaldehyde resins. FRP also are capable of using a thinner wall for the same pressure rating as unreinforced polymers. This can be useful for large diameter plasma vacuum chambers.

In some embodiments, a coating may be formed on the walls of a polymeric vacuum chamber. A coating may be used to inhibit molecular adsorption and absorption of unwanted species. Coating of a polymeric vacuum chamber may be achieved by introducing a coating monomer or a reactive gas which may be formed into coating, into the polymeric vacuum chamber. A plasma may be created within the polymer vacuum chamber containing the monomer or reactive gas, to aid the deposition of the coating layer onto the walls of the polymeric vacuum chamber.

One or more vacuum outlets 220 may be solvent welded to a polymer vacuum chamber 210. Other techniques may be used to couple the polymer components including heat fusion and adhesive fixing. In an embodiment, vacuum outlet 220 is formed by coupling a polymer tubing-flange adapter 242 to one or both ends of the polymer vacuum chamber. Tubing-flange adapters 242 may be solvent-welded to the end of the polymer vacuum chamber using well known techniques for welding tubing pieces together. Vacuum outlets may be coupled to a vacuum system using a matching flanged adapter 244 which is used to removably couple the vacuum chamber to a vacuum source. A seal 246 (e.g., a gasket or an o-ring) may be positioned between the flange 242 coupled to the vacuum chamber and the flange 244 coupling the vacuum chamber to the vacuum source. Seal 246 may inhibit leakage of an ambient atmosphere into the vacuum chamber during use. The vacuum chamber and the vacuum source flanges may be coupled to each other using one or more fasteners (e.g., bolts 248) or via a hinge clamp connector.

Vacuum outlets 220 may be coupled together using vacuum conduits 250 such that both vacuum outlets are coupled to a single vacuum source. In an embodiment, vacuum fittings 240 are coupled to one or more vacuum conduits 250. Vacuum conduits 250 include one or more curved connectors 252 and one or more straight connectors 254. Additionally, vacuum conduits may include a flexible conduit 256. Flexible conduit 256 may allow the ends of the vacuum conduit (which are coupled to the vacuum outlet flanges when assembled) to be moved away from the vacuum flanges, assisting assembly and disassembly of the vacuum tubing from the vacuum chamber. A T-connector 257 couples conduits from one end of the vacuum chamber to conduits from the opposing end of the vacuum chamber. In an embodiment, most, if not all, of the vacuum conduits may be formed from a polymer material. Forming the vacuum conduits from a polymer material may help further reduce the cost and weight of the plasma reactor. It also creates a single unitary component that includes all of the necessary tubing for making a single connection to a vacuum source and a single connection to a monomer/reactive gas source. Having the vacuum conduits as a part of the polymer vacuum chamber creates a modular component that can be easily replaced in the event of failure.

In an embodiment, two electrodes (not shown) are placed at an appropriate spacing from each other to allow the capacitive generation of a plasma between the electrodes. The two electrodes may be placed inside the polymeric vacuum chamber or outside of the vacuum chamber along the length of the tube or around the tube. Since most polymer materials are non-conductive, it is possible to position the electrodes outside of the vacuum chamber, rather than inside the chamber. An RF generator is coupled to one of the electrodes with the other electrode being grounded.

In an alternate embodiment, an electrically conductive wire (e.g., a copper wire) may be coiled around the vacuum chamber for use in inductively producing a plasma. In this embodiment, an electrical current passing through the coil induces electric currents in the gases disposed in the vacuum chamber, causing the formation of a plasma within the vacuum chamber.

### EXAMPLES

The following examples are included to demonstrate preferred embodiments of the invention. It should be appreciated by those of skill in the art that the techniques disclosed in the examples which follow represent techniques discovered by the inventor to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

### Example 1

### Acrylic Chamber

In Example 1, an acrylic vacuum chamber was used as the reactor material for a plasma deposition of a hydrophobic film on an article of footwear, with a plasma formed in the chamber. The acrylic vacuum chamber was fabricated as a direct replacement for the original quartz chamber of a Branson IPC 3000 Series Barrel Plasma device that had suffered multiple failures and was ultimately non-repairable. The acrylic vacuum chamber was constructed out of ½ inch wall thickness clear acrylic tubing, two feet long, with an inside diameter of 13 inches and outside diameter of 14 inches. A ¼ inch groove was milled on either end of the chamber to retain an o-ring. Two 1.5 inch sheets of acrylic were used to serve as an end caps with one of the ends containing a gas inlet and vacuum exhaust holes. The resulting deposited hydrophobic film using an acrylic vacuum chamber is evidence of little to no leaching or permeating gases that could cause a hydrophilic film to be deposited in the chamber.

### Example 2

### PVC Chamber

A PVC chamber was manufactured beginning with 24 inches of schedule 80 clear PVC pipe produced by Harvel Plastics. An unplasticized white socket fit PVC reducer was solvent welded to the main tube on the vacuum exhaust end. Into this reducer was solvent welded a section of ¾inch white PVC pipe. Onto this ¾inch pipe was solvent welded a PVC KF40 adapter purchased from PChemLabs.com. A single hole was drilled and tapped in the side of the schedule 80 clear PVC pipe and a male pipe thread to tubing adapter screwed into the hole with PTFE tape acting as a sealant. To this adapter was attached a polymer tube to deliver the monomer for the PECVD reaction. The end opposite the vacuum exhaust is the load end which is made by solvent welding a 4 inch flange fitting made by Spears Manufacturing. A blind flange was made out of ¾inch thick gray sheet PVC with bolt holes corresponding to the bolt holes in the Spears solvent weld flange. Between these two flanges was placed a neoprene gasket and bolts, nuts, and washers were assembled in all the bolt holes to create a vacuum tight seal. Two sheets of copper were placed on opposite sides of the schedule 80 PVC pipe and attached to a radio frequency power supply and ground. An Edwards model 28 vacuum pump, manual isolation valve, stainless steel KF40 bellows, and MKS 651 pressure gauge were all attached to the sealed PVC chamber. The chamber thus configured was allowed to outgas for 24 hours before testing.

Within 48 hours the pressure gauge registered pressures below 0.1 Pa which was the lower limit of the vacuum pump and lower accuracy limit for the pressure gauge. The isolation valve was closed to determine a leak back rate (LBR) as a measure of chamber integrity, permeability, and virtual leaks. With correct assembly, LBRs less than 0.1 Pa per minute were deemed sufficient to proceed to plasma firing and deposition testing. Non-chlorinated monomers were used to create PECVD films on silicon wafers and these would be tested by profilometery, XPS and FTIR to verify film thickness and composition. Chlorine levels in the deposited films were below the detection limit of these analytical methods, thus no significant material from the PVC chamber was outgassed and incorporated into the PECVD films.

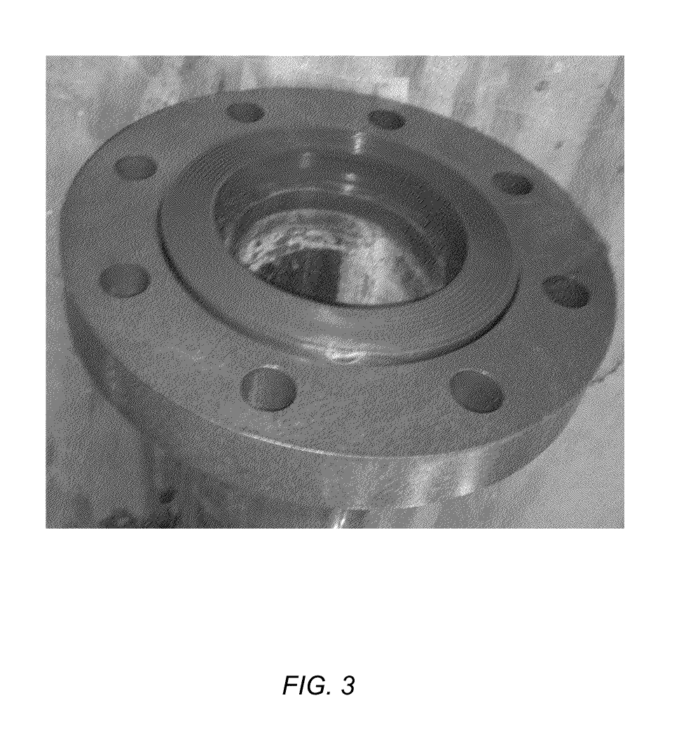

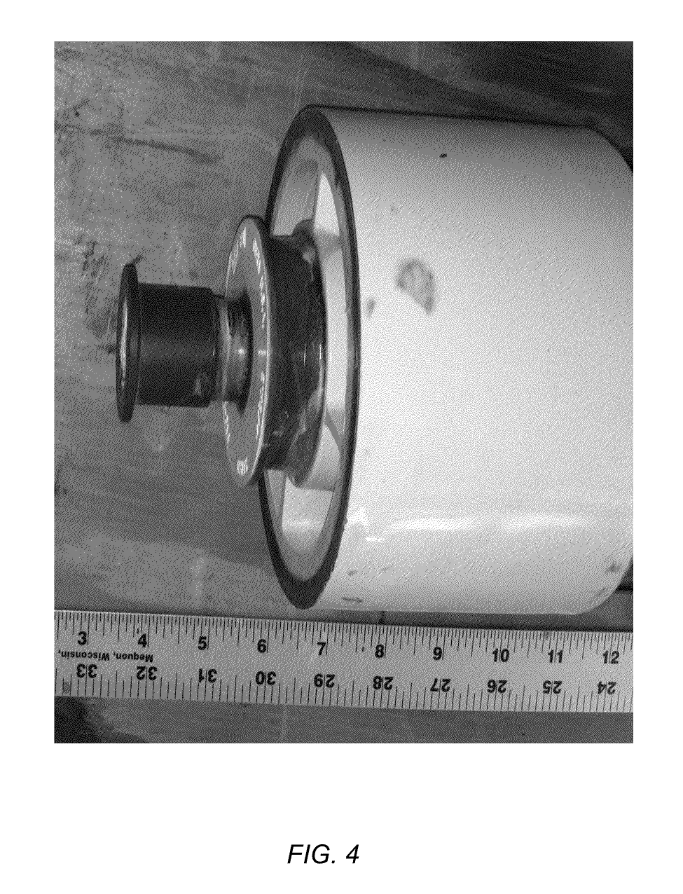

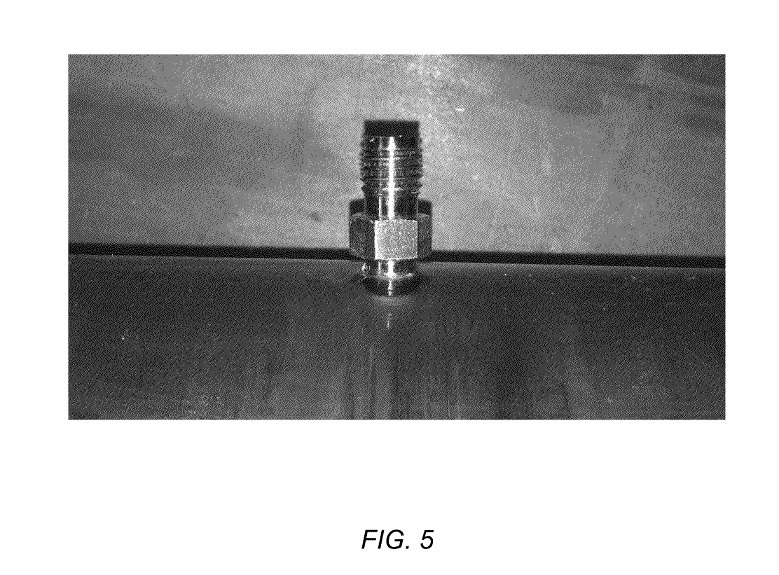

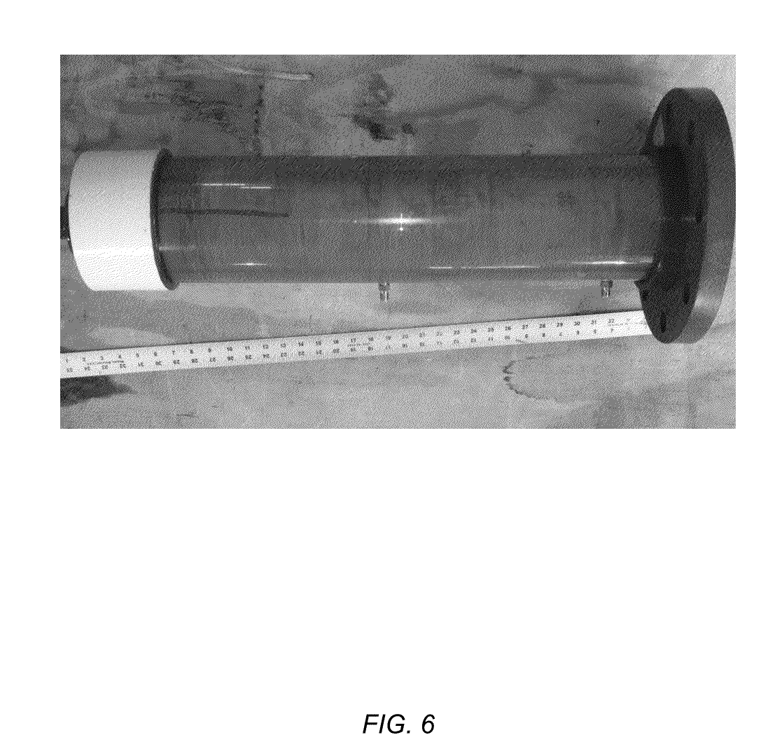

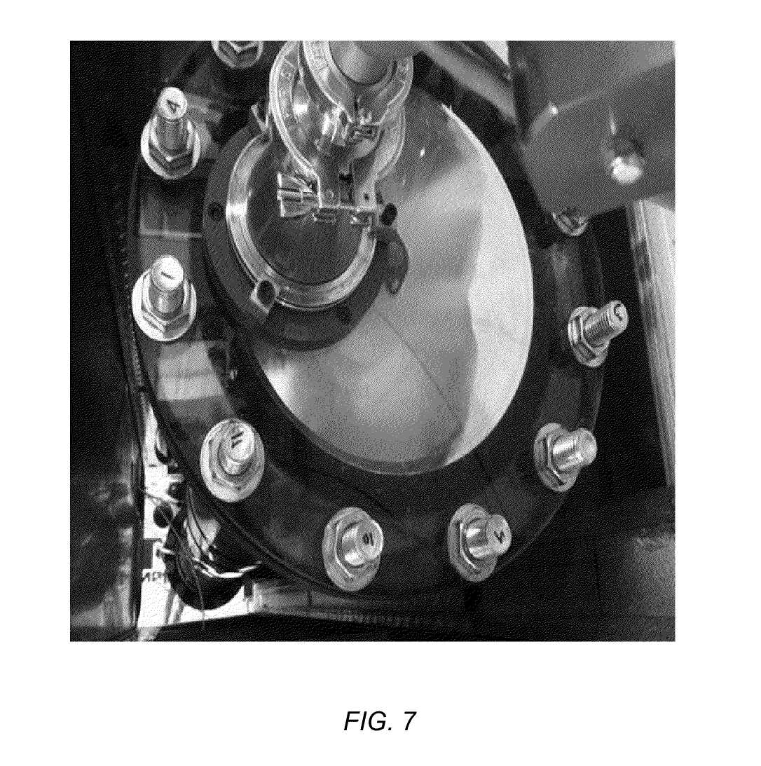

Chambers with diameters of 24 inches have been similarly created and lengths of over 40 feet have been demonstrated to be readily constructed. FIG. 3 depicts a 4 inch diameter PVC plasma chamber at the work piece load end. FIG. 4 depicts a 4 inch diameter PVC plasma chamber at the vacuum port end. FIG. 5 depicts a 4 inch diameter PVC plasma chamber at the monomer/gas inlet port. FIG. 6 depicts the assembled vacuum chamber. FIG. 7 depicts a 12 inch PVC plasma chamber with acrylic end plate in service.

### Example 3

### Fiber Reinforced Plastic Chamber

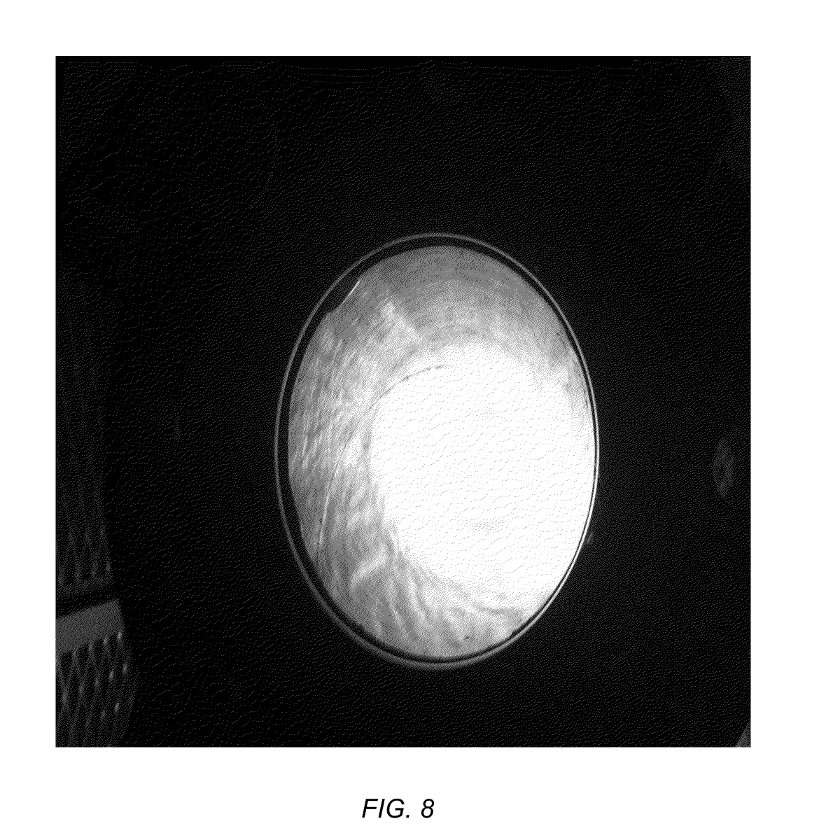

A fiber reinforced polymer (FRP) chamber was manufactured beginning with 4.5 inch low pressure Bondstrand 3000A pipe. On the vacuum side was epoxied a PVC plug with a stainless steel KF40 bulkhead fitting for the vacuum exhaust side. On the work piece load side, the outer diameter of the fiberglass pipe was reduced to fit inside a 4 inch Van Stone flange which was epoxied to the pipe. A clear acrylic endplate was used to seal an end of the reactor chamber. A plasma was easily struck and maintained in this chamber as shown in FIG. 8.

### Example 4

### Outgassing Data from Plastic Chambers

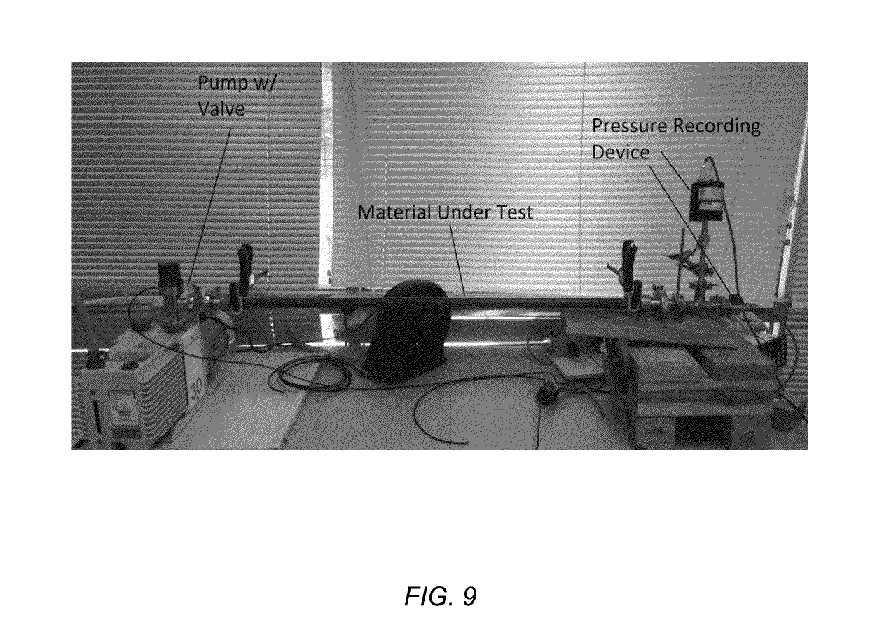

FIG. 9 shows an apparatus used to test the outgassing of multiple materials over time. The internal surface area of the various tube materials used were held constant at 99 in² by controlling the length of tubes (ranging from 36-44 in) with similar inner diameters ranging from 0.7-0.9 in. LBRs were collected from different tube materials by allowing the tube to be evacuated using an Edwards 30 rotary vane pump and monitored by a MKS 925 Micropirani pressure transducer. The tubes were pumped down in cycles with the main pumping valve being open for 20 min, and then the tubes were allowed to rise in pressure with the valve closed for 10 min. LBRs were calculated by taking the pressure after the valve had been closed for 9.5 min and subtracting the pressure after the valve had been closed for 0.5 min and dividing that by 9 min to result in a mTorr/min leak back rate. It is important to note that absolute LBR values are highly dependent on the volume and the surface area of the vacuum chamber. A small leak in a large volume will not change LBR as much as a small leak in a small volume.

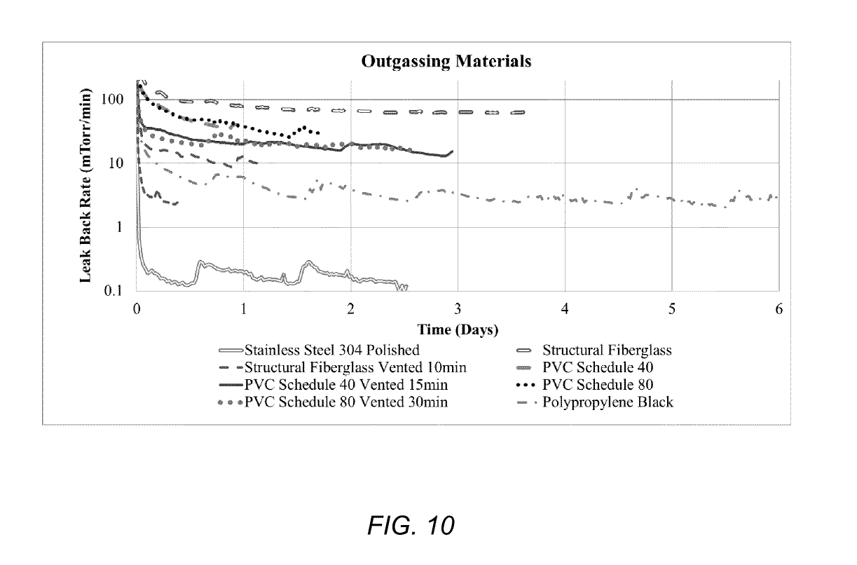

Base pressures measured in the apparatus in FIG. 9 on all tubes, including the stainless steel tube, ranged from 0.1 Pa-0.2 Pa suggesting that base pressure alone is not a good metric to use in finding a suitable material for PECVD chamber construction. FIG. 10 is a logarithmic plot of LBR as a function of time for some materials. The curves distinguished as “vented” are data collected from the same pipe after it was vented to atmospheric conditions and then placed again under vacuum. The duration of the time the tubes were at atmospheric pressure ranged from 10-30 min. In all polymeric materials tested thus far (PVC, polypropylene, and fiberglass), lower LBRs were obtained in shorter amount of time after the tubes were vented than during the initial pumping of the tube and in most cases lower overall LBRs were obtained. This tells us that these materials are outgassing and volatile compounds are leaching out of the materials; but once the volatiles are leached out the materials, they will perform better and provide less unwanted gases when used as PECVD chambers. The bumps in the curves are due to fluctuations in the temperature of the tube during different parts of the day. Cycling pressures in these materials by venting for relatively short periods of time also aids in achieving lower LBRs. This was surprising since one would think that gases would adsorb and absorb to the surface of the material after venting it to atmosphere. Plasma deposition of films onto the reactor walls of these chambers (especially hydrophobic and omniphobic films) provides additional reduction of unwanted absorbates, leaching volatile compounds, and gas permeation through the polymeric walls. This became evident by a discovered “break-in” period of several batches needed for treating substrates in most of our polymeric based PECVD reactors.

FIG. 10 additionally shows that by changing the thickness of a material from schedule 40 to schedule 80 PVC, little change is seen in the LBR of the tubes for both its initial pump down and after it was previously vented. This suggest that gas permeation through the PVC wall is not a problem at these pipe thicknesses and pressures where the dominate determination of base pressure is surface desorption and volatiles leaching out of the material. The fact that the tubes designated as vented behave similarly suggests that wall thickness also has little effect on the amount surface desorption and volatiles leaching out of the material under these conditions.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A vacuum chamber of a plasma reactor, comprising a body, wherein the body is composed of a polymer material.

2. The vacuum chamber of claim 1, further comprising one or more ports to allow the entry of gases and monomers.

3. The vacuum chamber of claim 1, further comprising one or more conduits coupled to the body, wherein the one or more conduits transfer a vacuum to the end of the conduit.

4. The vacuum chamber of claim 3, wherein one or more vacuum chamber conduits are formed from a polymer material.

5. The vacuum chamber of claim 1, wherein a coating is formed on the interior walls of the body, wherein the coating layer inhibits molecular adsorption or absorption of unwanted species by the interior walls of the vacuum chamber.

6. A plasma reactor comprising a vacuum chamber, wherein the vacuum chamber comprises a body, wherein the body is composed of a polymeric material.

7. The plasma reactor of claim 6, wherein the vacuum chamber further comprises one or more ports to allow the entry of gases and monomers.

8. The plasma reactor of claim 6, wherein the vacuum chamber further comprises one or more conduits coupled to the body, wherein the one or more conduits transfer a vacuum to the end of the conduit.

9. The plasma reactor of claim 8, wherein one or more vacuum chamber conduits are formed from a polymer material.

10. The plasma reactor of claim 6, wherein a coating is formed on the interior walls of the vacuum chamber, wherein the coating layer inhibits molecular adsorption or absorption of unwanted species by the interior walls of the vacuum chamber.

11. The plasma reactor of claim 6, further comprising two or more electrodes positioned outside of the polymer vacuum chamber, wherein a capacitive discharge between the electrodes creates a plasma within the polymer vacuum chamber.

12. The plasma reactor of claim 6, further comprising an electrically conductive coil surrounding the vacuum chamber, wherein passage of a current through the electrically conductive coil inductively produces a plasma within the polymer vacuum chamber.

13. A method of making a coated substrate comprising:
placing the substrate to be coated in a plasma reactor, wherein the plasma reactor comprises a vacuum chamber comprising a body composed of a polymeric material;
introducing a monomer or reactive gas; and
creating a plasma within the polymer vacuum chamber containing monomer or reactive gas.

14. The method of claim 13, wherein the vacuum chamber further comprises one or more ports to allow the entry of gases and monomers.

15. The method of claim 13, wherein the vacuum chamber further comprises one or more conduits coupled to the body, wherein the one or more conduits transfer a vacuum to the end of the conduit.

16. The method of claim 15, wherein one or more vacuum chamber conduits are formed from a polymer material.

17. The method of claim 13, wherein a coating is formed on the interior walls of the vacuum chamber, wherein the coating layer inhibits molecular adsorption or absorption of unwanted species by the interior walls of the vacuum chamber.

18. The method of claim 13, wherein the plasma reactor further comprises two or more electrodes positioned outside of the polymer vacuum chamber, wherein a capacitive discharge between the electrodes creates a plasma within the polymer vacuum chamber.

19. The method of claim 13, wherein the plasma reactor further comprises an electrically conductive coil surrounding the vacuum chamber, wherein passage of a current through the electrically conductive coil inductively produces a plasma within the polymer vacuum chamber.
